(19) United States
(12) Patent Application Publication
(10) Pub. No.: US 2003/0048045 A1
(43) Pub. Date: Mar. 13, 2003

(54) Piezo actuator

(76) Inventors: Michael Jupe, Ludwigsburg (DE); Klaus-Peter Schmoll, Lehrensteinsfeld (DE)

Correspondence Address: Striker Striker & Stenby, 103 East Neck Road, Huntington, NY, 11743, US

(21) Appl. No.: 10/181,580

(22) PCT Filed: Jan. 13, 2001
(86) PCT No.: PCT/DE01/00126

(51) Int. Cl. H01L 41/08

(52) U.S. Cl. 310/354

(57) ABSTRACT

A piezoelectric actuator for operating a mechanical component, in particular for an injector for metering fuel in an internal combustion engine, is proposed in which one head part and one foot part (3, 4) are present, between which a piezoelectric element (2) is clamped in the direction of operation. At least one centering body (11, 12; 14, 15) is present, which is clamped between the piezoelectric element (2) and the head part and/or the foot part (3, 4), and a clamping device (5, 6; 12, 13) is present that is arranged between the head part and the foot part (3, 4) to clamp the piezoelectric element (2). The centering body can be a cone (11, 12) or a ball (14, 15), for example.

### BACKGROUND OF THE INVENTION

The invention concerns a piezoelectric actuator, in particular for operating a mechanical component, for example for an injector for metering fuel in an internal combustion engine according to the generic features of the main claim.

It is generally known that, utilizing the “piezoelectric effect”, a piezoelectric element can be developed out of a material having a suitable crystal structure. When an external electrical voltage is applied, a mechanical reaction of the piezoelectric element takes place that, depending on the crystal structure and the areas where the electrical voltage is applied, represents a push or pull in a specifiable direction.

It is also known in and of itself that nozzles or valves for the fuel metering of an internal combustion engine have pressure or control pins that require high pressures and rapid and exact reaction times. Such an injection system is described, for example, in the “Kraftfahrtechnisches Taschenbuch” [Automotive Handbook], VDI-Verlag 1987, 20^{th} Edition, pages 391, 392. In the case of this known arrangement, the piezoelectric actuator is used to open and close the needle in the nozzle, whereby the assembly of the total system is very costly and requires a high level of accuracy.

A particular difficulty in the case of the known arrangement involves mounting the piezoelectric actuator in the middle, centered in relation to a head part and a foot part and holding these parts together in such a fashion that they do not detach from each other when the parts are subsequently cast and installed. Typically, the parts are assembled here by means of an adhering procedure, and centering generally takes place visually during assembly.

### ADVANTAGE OF THE INVENTION

The piezoelectric actuator initially described for operating a mechanical component, e.g., for an injector for metering fuel in an internal combustion engine, advantageously comprises a head part and a foot part, between which a piezoelectric element is clamped in the direction of operation. At least one centering body is present here, which lies between the piezoelectric element and the head part and/or the foot part. Furthermore, a clamping device is provided that is arranged between the head part and the foot part to clamp the piezoelectric element.

Using the arrangement according to the invention, it is advantageously achieved that the entire piezoelectric actuator is centered with head and foot part, which prevents a single-sided mechanical stressing of the piezoelectric element and, therefore, of the entire piezoelectric actuator, which therefore increases the durability of the piezoelectric actuator.

In the case of a first exemplary embodiment, the centering body is advantageously a cone, a truncated cone, or a similar body that is held either on the piezoelectric element or on the head and/or foot part and engages in a corresponding recess in the facing part in each case for the purpose of clamping. If a cone is present at the head part and at the foot part, for example, an appropriate cavity or recess would have to be produced on the corresponding counterpiece—the piezoelectric element in this case—so that the head part and the foot part are centered with the piezoelectric element.

In the case of another likewise advantageous exemplary embodiment, the centering body is a ball or a similar body that engages in a corresponding recess on the piezoelectric element and on the head and/or foot part for the purpose of clamping. A form cutter, e.g., with a spherical head, can be used to produce the recesses or cavities on the head and/or foot part. The spherical profile can be taken into account in the piezoelectric element when sintering the ceramic of the piezoelectric element, for example, or it can be produced by means of copy-milling or grinding in.

In order to retain the previously mentioned centering, the clamping element is composed of at least two cords that are fastened by means of their ends at the head and foot part in each case in such a fashion that they each clamp the piezoelectric element, preferably on opposite sides.

The cords, preferably nylon cords, should remain after installation for reasons of stability.

A further advantageous variant of the invention involves holding the head and foot part together via a wave spring. This wave spring can be secured on the head part by means of laser welding or adhesive bonding, for example, and on the foot part by means of hanging-in.

The electrical contacting of the piezoelectric element can take place in simple fashion after assembly by means of two pins that stand vertically upwardly. After that, the centered piezoelectric actuator can be handled as a unit in the further assembly process.

These and further features of preferred further developments of the invention arise not only from the claims but from the description and the drawings as well, and the individual features—on their own in each case or in plurality—can be realized in the form of subcombinations in the case of the exemplary embodiment of the invention and in other fields, and can represent advantageous and strictly speaking patentable embodiments, for which protection is claimed here.

### SUMMARY OF THE DRAWINGS

Exemplary embodiments of the piezoelectric actuator according to the invention are explained with reference to the drawings.

FIG. 1 is a sectional drawing and a cross section through a piezoelectric actuator for operating an injector for metering fuel in an internal combustion engine having two wave springs to clamp a piezoelectric element and a fixing in position of the piezoelectric element with two cones;

FIG. 2 is a sectional drawing through a piezoelectric actuator that, in deviation from FIG. 1, is provided with two cords to clamp the piezoelectric actuator;

FIG. 3 is a sectional drawing through a piezoelectric actuator that, in deviation from FIG. 1, is provided with two balls to fix the piezoelectric element in position;

FIG. 4 is a detailed drawing of the head and foot part of the piezoelectric actuator having cones for fixation;

FIG. 5 is a detailed drawing of the head and foot part of the piezoelectric actuator having balls for fixation;

FIG. 6 is a detailed drawing of the piezoelectric element having cones for fixation, and

FIG. 7 is a detailed drawing of the piezoelectric element having balls for fixation.

### DESCRIPTION OF THE PREFERRED EMBODIMENTS

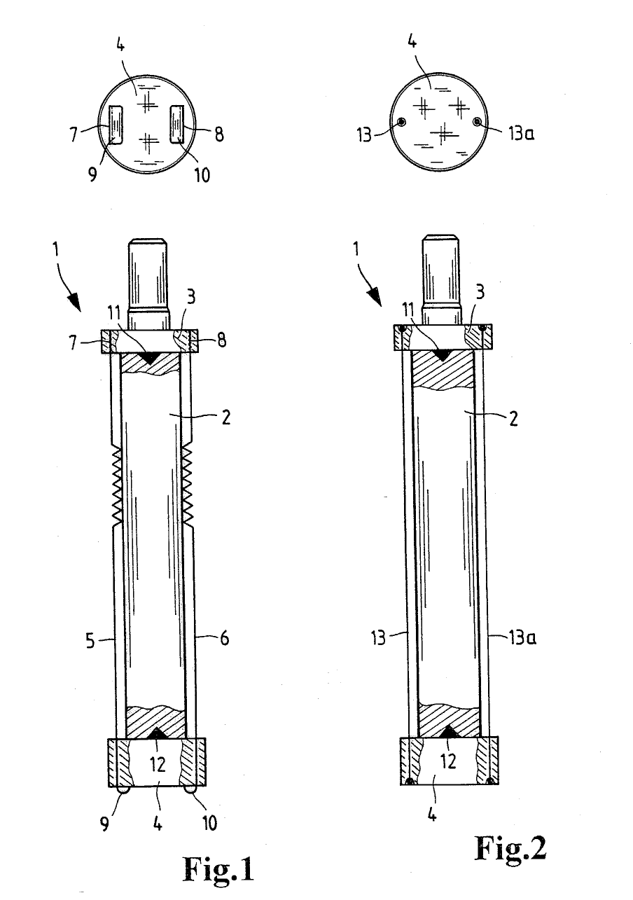

The view according to FIG. 1 is a piezoelectric actuator 1 having a piezoelectric element 2 that is clamped between a head part 3 and a foot part 4. Here, as is known per se, the piezoelectric element 2 is formed out of a quartz material having a suitable crystal structure, so that, utilizing the “piezoelectric effect”, when an external electrical voltage is applied, a mechanical reaction of the piezoelectric element 2 takes place in the direction of the clamping.

The arrangement according to FIG. 1 is clamped with wave springs 5 and 6 that are welded, preferably laser-welded, on the top on the head part 3 at points 7 and 8 and, on the bottom, are hung into appropriate devices 9 and 10.

The piezoelectric element 2 is clamped in the center between the head part 3 and the foot part 4 by means of centering bodies 11 and 12. The centering bodies here are cones 11 and 12 that are applied on the head and foot part 3, 4 and engage in corresponding recesses or cavities in the piezoelectric element 2.

In the case of the arrangement according to FIG. 2, the clamping of the piezoelectric element is carried out using nylon cords 13 and 13a, each of which is fastened at the head part 3 and at the foot part 4.

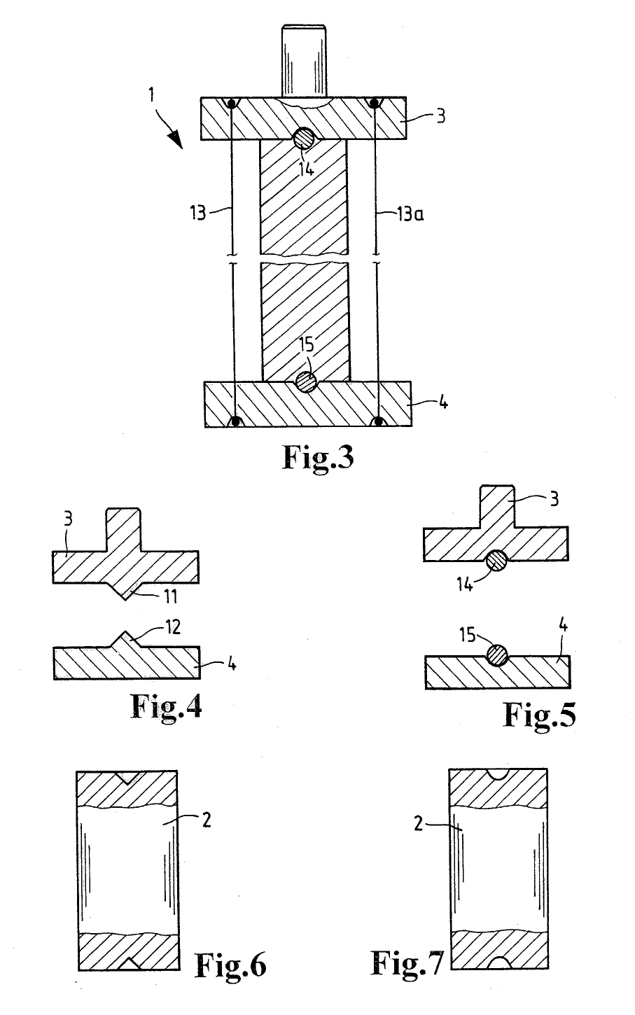

An alternative exemplary embodiment of the centering using balls 14 and 15 is shown in FIG. 3, in which the clamping of the piezoelectric element can also be carried out using nylon cords 13 and 13a, for example, which said nylon cords are fastened at the head part 3 and at the foot part 4 in each case analogous to FIG. 2. The balls 14 and 15 come to rest here in appropriate recesses in the head part 3, in the foot part 4, and in the piezoelectric element 2 when the piezoelectric actuator 1 is assembled.

FIG. 4 is a detailed drawing of the head and foot part 3 and 4 of the piezoelectric actuator 1 having cones 11 and 12. FIG. 5 is a detailed drawing of the head and foot part 3 and 4 of the piezoelectric actuator 1 having balls 14 and 15. FIG. 6 is a corresponding detailed drawing of the piezoelectric element 2 for the arrangement having cones 11 and 12 (FIG. 4), and FIG. 7 is a corresponding detailed drawing of the piezoelectric element 2 for an arrangement having balls 14 and 15 (FIG. 5) for fixing the piezoelectric element 2 in position.

What is claimed is:

1. A piezoelectric actuator for operating a mechanical component, having
one head part and one foot part (3, 4), between which a piezoelectric element (2) is clamped in the direction of operation, having
at least one centering body (11, 12; 14, 15) that is clamped between the piezoelectric element (2) and the head part and/or the foot part (3, 4), and having
a clamping device (5, 6; 12, 13) that is arranged between the head part and the foot part (3, 4) to clamp the piezoelectric element (2).

2. The piezoelectric actuator according to claim 1, wherein
the centering body is a cone (11, 12), truncated cone or a similar body that is held either at the piezoelectric element (2) or at the head part and/or foot part (3, 4) and engages in a corresponding recess in the facing part in each case for the purpose of clamping.

3. The piezoelectric actuator according to claim 1, wherein
the centering body is a ball (14, 15) or a similar body that engages in a corresponding recess on the piezoelectric element (2) and on the head and/or foot part (3, 4) for the purpose of clamping.

4. The piezoelectric actuator according to one of the preceding claims wherein
the clamping element is composed of at least two cords (13, 13a) that are secured with their ends on the head part and the foot part (3, 4) in each case in such a fashion that they each clamp the piezoelectric element (2), preferably on opposite sides.

5. The piezoelectric actuator according to claim 4, wherein
the cords are nylon cords (13, 13a).

6. The piezoelectric actuator according to one of the preceding claims wherein
the clamping element is composed of at least two wave springs (5, 6) that are secured with their ends on the head and foot part (3, 4) in each case in such a fashion that they each clamp the piezoelectric element (2), preferably on opposite sides.

7. The piezoelectric actuator according to claim 6, wherein
the wave springs (5, 6) are welded (7, 8) at one end with the head or foot part (3, 4) and, with the other end, are hung-in (9, 10) at the head part or foot part (3, 4).
